(19) United States
(12) Patent Application Publication
(10) Pub. No.: US 2024/0392194 A1
(43) Pub. Date: Nov. 28, 2024

(54) Post-Dry Etching Photoresist And Metal Containing Residue Removal Formulation

(71) Applicant: Versum Materials US, LLC, Tempe, AZ (US)

(72) Inventors: Chung-Yi Chang, New Taipei City (TW); Wen Dar Liu, Chupei City (TW); Jhih-Kuei Ge, New Taipei City (TW); Yi-Chia Lee, Chupei City (TW); Aiping Wu, Chandler, AZ (US)

(21) Appl. No.: 18/693,041

(22) PCT Filed: Sep. 20, 2022
(86) PCT No.: PCT/US2022/076685

§ 371 Date: Mar. 18, 2024

Related U.S. Application Data
(60) Provisional application No. 63/247,347, filed on Sep. 23, 2021.

(51) Int. Cl. C09K 13/08; C09K 13/00; G03F 7/42

(52) U.S. Cl. CPC C09K 13/08; C09K 13/00; G03F 7/425

(57) ABSTRACT

The disclosed and claimed subject matter relates to a stripping composition having a controlled oxide etch and ITO (Indium Tin oxide) etch as well as sidewall polymer and polymer etch residue removal capability and to a process for stripping and etching utilizing the composition.

### BACKGROUND

### Field

The disclosed and claimed subject matter relates to a stripping composition having a controlled oxide etch and ITO (Indium Tin oxide) etch as well as sidewall polymer and polymer etch residue removal capability and to a process for stripping and etching utilizing the composition.

### Related Art

During manufacturing in the microelectronic field, a photoresist thin film functions as a mask applied on a substrate material to form a pattern for later fabrication processes. A resist pattern could be formed by other photolithography steps. Normally, when using a resist film as a mask, a dry etching process then follows in order to etch other materials underneath the photoresist mask. For example, etchant gases can selectively attack the unprotected area of the substrate that is not covered by the photoresist film. During the plasma etching process, photoresist and exposed material related by-products are deposited as post etch residues on the surface of exposed photoresist and substrates.

The post etch residues could contain different materials depending on the substrates exposed during the plasma etching process. For example, aluminum and titanium containing residues could result from processing aluminum patterned substrate, silicon containing residues could result from the via patterned structure which are made from silicon oxide materials. All of these post-etch residues have to be completely cleaned before next step process to ensure the quality of final products.

Indium tin oxide (ITO) is one of widely used transparent conducting oxides due to its electrical conductivity and optical transparency. It is easy to be deposited as a thin film on glass, PET, and other substrates for various application, such as flat-panel displays, polymer-based electronics, thin film photovoltaics, LCD and LED displays, and OLED displays. ITO thin films can be deposited on substrate surfaces by physical vapor deposition, such as the various sputtering techniques.

Patterning of ITO substrates becomes more important for advanced packaging technology in which ITO layer is deposited on a silicon oxide substrate. Positive photoresists are normally used in ITO substrate patterning process. After a patterning process, a plasma etch process is then conducted to remove certain exposed materials. Positive photoresists thereafter need to be fully or partially removed, normally by wet chemistry processing.

Many photoresist strippers and residue removers have been proposed for fully or partially removing photoresist films. However, for ITO patterning process, traditional photoresists as well as post etch residues are difficult to remove and clean due to the formation of the metal containing by-products on photoresist and metal side-wall surface. Also, the photoresist surface becomes harder during the dry etch process as a protection layer to prevent the effective removal. Consequently, commonly used alkanolamine solvent based solutions cannot effectively and/or efficiently dissolve photoresist the films.

Additionally, many photoresist strippers and post etch cleaning solutions contain environmentally unfriendly organic solvents, such as N-Methyl-2-pyrrolidone (NMP) and dimethyl sulfoxide (DMSO), and dimethylacetamide (DMAC). Replacing those organic solvents with more environmentally friendly solvents is needed in development of new photoresist strippers and post etch cleaning solutions.

Therefore, there is need to develop a new environmentally friend chemistry without NMP and DMAC to effectively dissolve photoresist layers by breaking through the protective layer formed by post etch residue on photoresist and ITO metal side walls. In addition, the chemistry also needs to be compatible to exposed ITO and SiO₂ materials. The chemistry must also efficiently clean the post etch residues with compatibility to exposed materials.

### SUMMARY

The disclosed and claimed subject matter provides an aqueous acidic stripping and cleaning composition for the removal of organic materials, organometallic residues, organosilicon residues, sidewall polymer (SWP) and inorganic residues which has controlled silicon oxide and ITO etch rates. The cleaning composition includes, consists essentially of or consists of:
(i) about 1% to about 10% by weight of one or more polyhydric alcohol;
(ii) about 50% to about 80% by weight of (iia) one or more organic water-soluble glycol ether solvent or (iib) one or more amide selected from diethyl formamide (DEF), N-methylformamide, N-ethylformamide, N,N-dimethylacetamide and N,N-dimethylpropionamide;
(iii) about 0.1% to about 0.5% by weight of a fluoride ion source including one or more of neat ammonium fluoride and neat HF;
(iv) about 1% to about 10% by weight of one or more buffer agent;
(v) about 10% to about 40% by weight of water; and
(vi) optionally one or more corrosion inhibitor.
   In one embodiment, the cleaning composition has a pH of more than about 3 and less than about 9. In one aspect of this embodiment, the cleaning composition has a pH of more than about 3 and less than about 6. In another embodiment, the cleaning composition has a pH of more than about 4 and less than about 6. In another embodiment, the cleaning composition has a pH of more than about 4 and less than about 7. In one embodiment, the ammonium fluoride is provided as a 40% aqueous solution.

The disclosed and claimed compositions are suitable for cleaning post etch residues and at least partially removing photoresist film present on surface of photoresist film and ITO and silicon oxide with compatibility to ITO and silicon oxide.

In one embodiment, the disclosed and claimed compositions are free of NMP, dimethylsulfoxide (DMSO), dimethyl acetamide (DMAC), N-methylpyrrolidone (NMP), gamma butyllactone, urea, hydrogen peroxide and the like. In other embodiments, the disclosed and claimed subject compositions are additionally or alternatively free of amidoxime compounds. In other embodiments, the disclosed and claimed subject compositions are additionally or alternatively free of hydroxylamine and derivatives thereof. In other embodiments, the disclosed and claimed subject compositions are additionally or alternatively free of metal-containing compounds. In other embodiments, the disclosed and claimed subject compositions are additionally or alternatively free of corrosion inhibitors.

Among other things, the disclosed and claimed compositions provide controlled etch and sidewall polymer removal capability.

In addition, the disclosed and claimed compositions provide good cleaning performance to completely clean Al and Ti metal containing and silicon containing post etch residues with compatibility to exposed substrates such as aluminum and titanium.

The disclosed and claimed subject matter further includes a method for stripping which provides for a controlled silicon oxide and ITO etch utilizing the disclosed and claimed compositions.

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The order of discussion of the different steps described herein has been presented for clarity's sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates an embodiment of the cleaning process for a patterned ITO surface of the disclosed and claimed subject matter.

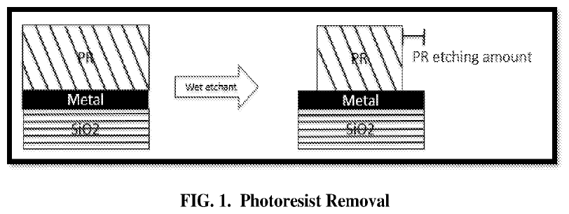

### DETAILED DESCRIPTION

All references, including publications, patent applications, and patents, cited herein are hereby incorporated by reference to the same extent as if each reference were individually and specifically indicated to be incorporated by reference and were set forth in its entirety herein.

The ensuing detailed description provides preferred exemplary embodiments only, and is not intended to limit the scope, applicability, or configuration of the disclosed and claimed subject matter. Rather, the ensuing detailed description of the preferred exemplary embodiments will provide those skilled in the art with an enabling description for implementing the preferred exemplary embodiments of the disclosed and claimed subject matter. Various changes may be made in the function and arrangement of elements without departing from the spirit and scope of the disclosed and claimed subject matter, as set forth in the appended claims.

The use of the terms “a” and “an” and “the” and similar referents in the context of describing the disclosed and claimed subject matter (especially in the context of the following claims) are to be construed to cover both the singular and the plural, unless otherwise indicated herein or clearly contradicted by context.

As used herein and in the claims, the terms “comprising.” “comprises,” “including” and “includes” are inclusive or open-ended and do not exclude additional unrecited elements, composition components, or method steps. Accordingly, these terms encompass the more restrictive terms “consisting essentially of” and “consisting of.” Unless specified otherwise, all values provided herein include up to and including the endpoints given, and the values of the constituents or components of the compositions are expressed in weight percent of each ingredient in the composition.

In compositions “consisting essentially of” recited components, such components may add up to 100 weight % of the composition or may add up to less than 100 weight %. Where the components add up to less than 100 weight %, such composition may include some small amounts of a non-essential contaminants or impurities. For example, in one such embodiment, the cleaning composition can contain 2% by weight or less of impurities. In another embodiment, the cleaning composition can contain 1% by weight or less than of impurities. In a further embodiment, the cleaning composition can contain 0.05% by weight or less than of impurities. In other such embodiments, the ingredients can form at least 90 wt %, more preferably at least 95 wt %, more preferably at least 99 wt %, more preferably at least 99.5 wt %, most preferably at least 99.9 wt %, and can include other ingredients that do not material affect the performance of the cleaning compositions. Otherwise, if no significant non-essential impurity component is present, it is understood that the combination of all essential constituent components will essentially add up to 100 weight %.

In some embodiments, the disclosed and claimed subject matter is free of amidoxime compounds. In some embodiments, the disclosed and claimed subject matter is free of metal-containing compounds.

All methods described herein can be performed in any suitable order unless otherwise indicated herein or otherwise clearly contradicted by context. The use of any and all examples, or exemplary language (e.g., “such as”) provided herein, is intended merely to better illuminate the disclosed and claimed subject matter and does not pose a limitation on the scope of the disclosed and claimed subject matter unless otherwise claimed. No language in the specification should be construed as indicating any non-claimed element as essential to the practice of the disclosed and claimed subject matter.

Preferred embodiments of this disclosed and claimed subject matter are described herein, including the best mode known to the inventors for carrying out the disclosed and claimed subject matter. Variations of those preferred embodiments may become apparent to those of ordinary skill in the art upon reading the foregoing description. The inventors expect skilled artisans to employ such variations as appropriate, and the inventors intend for the disclosed and claimed subject matter to be practiced otherwise than as specifically described herein. Accordingly, this disclosed and claimed subject matter includes all modifications and equivalents of the subject matter recited in the claims appended hereto as permitted by applicable law. Moreover, any combination of the above-described elements in all possible variations thereof is encompassed by the disclosed and claimed subject matter unless otherwise indicated herein or otherwise clearly contradicted by context.

The disclosed and claimed subject matter relates generally to compositions useful for the selective removal of titanium nitride and molybdenum metal from a microelectronic device having such material(s) thereon during its manufacture. The compositions disclosed herein are capable of removing both titanium nitride and molybdenum metal at rates that can be varied based on the particular need.

For case of reference, “microelectronic device” corresponds to semiconductor substrates, flat panel displays, phase change memory devices, solar panels and other products including solar cell devices, photovoltaics, and microelectromechanical systems (MEMS), manufactured for use in microelectronic, integrated circuit, energy collection, or computer chip applications. It is to be understood that the terms “microelectronic device,” “microelectronic substrate” and “microelectronic device structure” are not meant to be limiting in any way and include any substrate or structure that will eventually become a microelectronic device or microelectronic assembly. The microelectronic device can be patterned, blanketed, a control and/or a test device.

As defined herein, “low-k dielectric material” corresponds to any material used as a dielectric material in a layered microelectronic device, wherein the material has a dielectric constant less than about 3.5. Preferably, the low-k dielectric materials include low-polarity materials such as silicon-containing organic polymers, silicon-containing hybrid organic/inorganic materials, organosilicate glass (OSG), TEOS, fluorinated silicate glass (FSG), silicon dioxide, and carbon-doped oxide (CDO) glass. It is to be appreciated that the low-k dielectric materials may have varying densities and varying porosities.

“Substantially free” is defined herein as less than 2 wt %, preferably less than 1 wt %, more preferably less than 0.5 wt %, and most preferably less than 0.1 wt %. “Substantially free” also includes 0.0 wt %. The term “free of” means 0.0 wt % as commonly measured in the field.

As used herein. “about” or “approximately” is intended to correspond to ±5% of the stated value.

As defined herein, “photoresist etch residues” corresponds to any residue including photoresist material, or material that is a by-product of photoresist subsequent to an etching or aching step, as readily understood by the person skilled in the art.

As used herein, “fluoride” species correspond to species including an ionic fluoride (F) or covalently bonded fluorine. It is to be appreciated that the fluoride species may be included as a fluoride species or generated in situ.

Compositions of the disclosed and claimed subject matter may be embodied in a wide variety of specific formulations, as hereinafter more fully described.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.001 weight percent, based on the total weight of the composition in which such components are employed.

It will also be apparent to those skilled in the art that various modifications may be made in how the disclosed subject matter is practiced based on described aspects in the specification without departing from the spirit and scope of the disclosed subject matter disclosed herein.

As set forth above, the disclosed subject matter relates to cleaning compositions suitable for removing partially photoresist film and cleaning post etch residues while compatible to ITO and SiO₂.

In one embodiment, the cleaning compositions that include:
(i) about 1% to about 10% by weight of one or more polyhydric alcohol;
(ii) about 50% to about 80% by weight of (iia) one or more organic water-soluble glycol ether solvent or (iib) one or more amide selected from diethyl formamide (DEF), N-methylformamide, N-ethylformamide, N,N-dimethylacetamide and N,N-dimethylpropionamide;
(iii) about 0.1% to about 0.5% by weight of a fluoride ion source including one or more of neat ammonium fluoride and neat HF;
(iv) about 1% to about 10% by weight of one or more buffer agent;
(v) about 10% to about 40% by weight of water; and
(vi) optionally one or more corrosion inhibitor.
   In one aspect of this embodiment, the cleaning composition includes (iia) one or more organic water-soluble glycol ether solvent. In one aspect of this embodiment, the cleaning composition includes (iib) one or more amide selected from diethyl formamide (DEF), N-methylformamide, N-ethylformamide, N,N-dimethylacetamide and N,N-dimethylpropionamide. In one aspect of this embodiment, the cleaning composition includes (iib) one or more amide that includes diethyl formamide (DEF). In one aspect of this embodiment, the cleaning composition includes (vi) the one or more corrosion inhibitor. In one aspect of this embodiment, the cleaning composition has a pH of more than about 3 and less than about 9. In one aspect of this embodiment, the cleaning composition has a pH of more than about 3 and less than about 6. In another embodiment, the cleaning composition has a pH of more than about 4 and less than about 6. In one aspect of this embodiment, the cleaning composition has a pH of more than about 4 and less than about 7.

In one embodiment, the cleaning compositions consist essentially of:
(i) about 1% to about 10% by weight of one or more polyhydric alcohol;
(ii) about 50% to about 80% by weight of (iia) one or more organic water-soluble glycol ether solvent or (iib) one or more amide selected from diethyl formamide (DEF), N-methylformamide, N-ethylformamide, N,N-dimethylacetamide and N,N-dimethylpropionamide;
(iii) about 0.1% to about 0.5% by weight of a fluoride ion source including one or more of neat ammonium fluoride and neat HF;
(iv) about 1% to about 10% by weight of one or more buffer agent;
(v) about 10% to about 40% by weight of water; and
(vi) optionally one or more corrosion inhibitor.

In one aspect of this embodiment, the cleaning composition includes (iia) one or more organic water-soluble glycol ether solvent. In one aspect of this embodiment, the cleaning composition includes (iib) one or more amide selected from diethyl formamide (DEF), N-methylformamide, N-ethylformamide, N,N-dimethylacetamide and N,N-dimethylpropionamide. In one aspect of this embodiment, the cleaning composition includes (iib) one or more amide that includes diethyl formamide (DEF). In one aspect of this embodiment, the cleaning composition includes (vi) the one or more corrosion inhibitor. In one aspect of this embodiment, the cleaning composition has a pH of more than about 3 and less than about 9. In one aspect of this embodiment, the cleaning composition has a pH of more than about 3 and less than about 6. In another embodiment, the cleaning composition has a pH of more than about 4 and less than about 6. In one aspect of this embodiment, the cleaning composition has a pH of more than about 4 and less than about 7.

In one embodiment, the cleaning compositions consist of:
(i) about 1% to about 10% by weight of one or more polyhydric alcohol;
(ii) about 50% to about 80% by weight of (iia) one or more organic water-soluble glycol ether solvent or (iib) one or more amide selected from diethyl formamide (DEF), N-methylformamide, N-ethylformamide, N,N-dimethylacetamide and N,N-dimethylpropionamide;
(iii) about 0.1% to about 0.5% by weight of a fluoride ion source including one or more of neat ammonium fluoride and neat HF;
(iv) about 1% to about 10% by weight of one or more buffer agent;
(v) about 10% to about 40% by weight of water; and
(vi) optionally one or more corrosion inhibitor.
   In one aspect of this embodiment, the cleaning composition includes (iia) one or more organic water-soluble glycol ether solvent. In one aspect of this embodiment, the cleaning composition includes (iib) one or more amide selected from diethyl formamide (DEF), N-methylformamide, N-ethylformamide, N,N-dimethylacetamide and N,N-dimethylpropionamide. In one aspect of this embodiment, the cleaning composition includes (iib) one or more amide that includes diethyl formamide (DEF). In one aspect of this embodiment, the cleaning composition includes (vi) the one or more corrosion inhibitor. In one aspect of this embodiment, the cleaning composition has a pH of more than about 3 and less than about 9. In one aspect of this embodiment, the cleaning composition has a pH of more than about 3 and less than about 6. In another embodiment, the cleaning composition has a pH of more than about 4 and less than about 6. In one aspect of this embodiment, the cleaning composition has a pH of more than about 4 and less than about 7.

In another embodiment, the cleaning compositions disclosed herein are substantially free of or free of at least one of 4-methylmorpholine N-oxide, trimethylamine N-oxide, peracetic acid, urea, hydrogen peroxide, amidoxime compounds, hydroxylamine, hydroxylamine derivatives and metal-containing compounds. In one aspect of this embodiment, the cleaning composition disclosed herein are substantially free of or free of all of 4-methylmorpholine N-oxide, trimethylamine N-oxide, peracetic acid, urea, hydrogen peroxide, amidoxime compounds and metal-containing compounds.

### Composition Ingredients

### (i) Polyhydric Alcohol

As noted above, the disclosed and claimed cleaning compositions include (i) one or more polyhydric alcohols. As used herein, “polyhydric alcohol” means a compound containing at least two hydroxyl groups. Polyhydric alcohol used in the present invention are preferably di- or tri-alcohols, such as (C₂-C₂₀) alkanediols and (C₃-C₂₀) alkanetriols, cyclic alcohols and substituted alcohols. Exemplary polyhydric alcohols include, but are not limited to, glycerol, ethylene glycol, propylene glycol (PG), diethylene glycol, dipropylene glycol, hexylene glycol, 1,2-butandiol, 1,4-butandiol and 2,3-butandiol. Preferred polyhydric alcohols include ethylene glycol, propylene glycol, glycerol and combinations thereof.

In some embodiments, the amount of the (i) one or more polyhydric alcohol in the disclosed and claimed compositions may be in a range having start and end points selected from the following list of weight percents: about 1, about 1.5, about 2, about 2.5, about 3, about 3.5, about 4, about 4.5, about 5, about 5.5, about 6, about 6.5, about 7, about 7.5, about 8, about 8.5, about 9, about 9.5 and about 10. In other embodiments the (i) one or more polyhydric alcohol in the disclosed and claimed compositions is from about 1% to about 10% by weight. In other embodiments the (i) one or more polyhydric alcohol in the disclosed and claimed compositions is from about 1% to about 5% by weight. In other embodiments the (i) one or more polyhydric alcohol in the disclosed and claimed compositions is from about 1% to about 7% by weight. In other embodiments the (i) one or more polyhydric alcohol in the disclosed and claimed compositions is from about 5% to about 10% by weight. In other embodiments the (i) one or more polyhydric alcohol in the disclosed and claimed compositions is from about 3% to about 7% by weight. In other embodiments the (i) one or more polyhydric alcohol in the disclosed and claimed compositions is from about 4% to about 6% by weight by weight of the solution.

(iia) Glycol Ether Solvent

As noted above, in some embodiments of the disclosed and claimed cleaning compositions includes (ii) one or more organic water-soluble glycol ether solvent. Examples of glycol ethers include butyl diglycol, ethylene glycol monomethyl ether, ethylene glycol monoethyl ether, ethylene glycol monobutyl ether, ethylene glycol dimethyl ether, ethylene glycol diethyl ether, diethylene glycol monomethyl ether, diethylene glycol monoethyl ether, diethylene glycol monopropyl ether, diethylene glycol monoisopropyl ether, diethylene glycol monobutyl ether (BDG), diethylene glycol monoisobutyl either, diethylene glycol monobenzyl ether, diethylene glycol dimethyl ether, diethylene glycol diethyl ether, triethylene glycol monomethyl ether, triethylene glycol dimethyl ether, polyethylene glycol monomethyl ether, diethylene glycol methyl ethyl ether, triethylene glycol ethylene glycol monomethyl ether acetate, ethylene glycol monoethyl ether acetate, propylene glycol methyl ether acetate, propylene glycol monomethyl ether, propylene glycol dimethyl ether, propylene glycol monobutyl ether, propylene glycol, monopropyl ether, dipropylene glycol monomethyl ether (DPM), dipropylene glycol monopropyl ether, dipropylene glycol monoisopropyl ether, dipropylene monobutyl ether, dipropylene glycol diisopropyl ether, tripropylene glycol monomethyl ether, 1-methoxy-2-butanol, 2-methoxy-1-butanol, 2-methoxy-2-methylbutanol, 1,1-dimethoxyethane and 2-(2-butoxyethoxy) ethanol. Preferred glycol ether solvents include diethylene glycol butyl ether (BDG).

In some embodiments, the amount of the (ii) one or more organic water-soluble glycol ether solvent in the disclosed and claimed compositions may be in a range having start and end points selected from the following list of weight percents: 50, 55, 59.5, 60, 65, 70, 75 and 80. In other embodiments the (ii) one or more organic water-soluble glycol ether solvent in the disclosed and claimed compositions is from about 50% to about 80% by weight. In other embodiments the (ii) one or more organic water-soluble glycol ether solvent in the disclosed and claimed compositions is from about 50% to about 70% by weight. In other embodiments the (ii) one or more organic water-soluble glycol ether solvent in the disclosed and claimed compositions is from about 50% to about 60% by weight.

In one embodiment, the (ii) one or more organic water-soluble glycol ether solvent comprises diethylene glycol butyl ether (BDG).

In one embodiment, the (ii) one or more organic water-soluble glycol ether solvent consists essentially of diethylene glycol butyl ether (BDG).

In one embodiment, the (ii) one or more organic water-soluble glycol ether solvent consists of diethylene glycol butyl ether (BDG). In a further aspect of this embodiment, the (ii) one or more organic water-soluble glycol ether solvent consists of about 50% to about 60% by weight of diethylene glycol butyl ether (BDG). In a further aspect of this embodiment, the (ii) one or more organic water-soluble glycol ether solvent consists of about 54% by weight of diethylene glycol butyl ether (BDG). In a further aspect of this embodiment, the (ii) one or more organic water-soluble glycol ether solvent consists of about 59% by weight of diethylene glycol butyl ether (BDG). In a further aspect of this embodiment, the (ii) one or more organic water-soluble glycol ether solvent consists of about 53.9% by weight of diethylene glycol butyl ether (BDG). In a further aspect of this embodiment, the (ii) one or more organic water-soluble glycol ether solvent consists of about 58.9% by weight of diethylene glycol butyl ether (BDG).

(iib) Amide

As noted above, in some embodiments the disclosed and claimed cleaning compositions includes (iib) one or more amide selected from diethyl formamide, N-methylformamide, N-ethylformamide, N,N-dimethylacetamide and N,N-dimethylpropionamide.

In some embodiments, the cleaning compositions include (iib) one or more amide that includes diethyl formamide (DEF). In one aspect of these embodiments, the compositions include about 50% to about 60% by weight of (iib) diethyl formamide. In one aspect of these embodiments, the compositions include about 55% to about 60% by weight of (iib) diethyl formamide. In one aspect of these embodiments, the compositions include about 58% to about 60% by weight of (iib) diethyl formamide. In one aspect of these embodiments, the compositions include about 58% to about 59% by weight of (iib) diethyl formamide. In one aspect of these embodiments, the compositions include about 51% by weight of (iib) diethyl formamide. In one aspect of these embodiments, the compositions include about 52% by weight of (iib) diethyl formamide. In one aspect of these embodiments, the compositions include about 53% by weight of (iib) diethyl formamide. In one aspect of these embodiments, the compositions include about 54% by weight of (iib) diethyl formamide. In one aspect of these embodiments, the compositions include about 55% by weight of (iib) diethyl formamide. In one aspect of these embodiments, the compositions include about 56% by weight of (iib) diethyl formamide. In one aspect of these embodiments, the compositions include about 57% by weight of (iib) diethyl formamide. In one aspect of these embodiments, the compositions include about 58% by weight of (iib) diethyl formamide. In one aspect of these embodiments, the compositions include about 58.1% by weight of (iib) diethyl formamide. In one aspect of these embodiments, the compositions include about 58.2% by weight of (iib) diethyl formamide. In one aspect of these embodiments, the compositions include about 58.3% by weight of (iib) diethyl formamide. In one aspect of these embodiments, the compositions include about 58.4% by weight of (iib) diethyl formamide. In one aspect of these embodiments, the compositions include about 58.5% by weight of (iib) diethyl formamide. In one aspect of these embodiments, the compositions include about 58.6% by weight of (iib) diethyl formamide. In one aspect of these embodiments, the compositions include about 58.7% by weight of (iib) diethyl formamide. In one aspect of these embodiments, the compositions include about 58.8% by weight of (iib) diethyl formamide. In one aspect of these embodiments, the compositions include about 58.9% by weight of (iib) diethyl formamide. In one aspect of these embodiments, the compositions include about 59% by weight of (iib) diethyl formamide. In one aspect of these embodiments, the compositions include about 60% by weight of (iib) diethyl formamide.

In some embodiments, the cleaning compositions include (iib) one or more amide that includes N-methylformamide. In one aspect of these embodiments, the compositions include about 50% to about 60% by weight of (iib)N-methylformamide. In one aspect of these embodiments, the compositions include about 55% to about 60% by weight of (iib)N-methylformamide.

In some embodiments, the cleaning compositions include (iib) one or more amide that includes N-ethylformamide. In one aspect of these embodiments, the compositions include about 50% to about 60% by weight of (iib)N-ethylformamide. In one aspect of these embodiments, the compositions include about 55% to about 60% by weight of (iib)N-ethylformamide.

In some embodiments, the cleaning compositions include (iib) one or more amide that includes N,N-dimethylacetamide. In one aspect of these embodiments, the compositions include about 50% to about 60% by weight of (iib) N,N-dimethylacetamide. In one aspect of these embodiments, the compositions include about 55% to about 60% by weight of (iib) N,N-dimethylacetamide.

In some embodiments, the cleaning compositions include (iib) one or more amide that includes N,N-dimethylpropionamide. In one aspect of these embodiments, the compositions include about 50% to about 60% by weight of (iib) N,N-dimethylpropionamide. In one aspect of these embodiments, the compositions include about 55% to about 60% by weight of (iib) N,N-dimethylpropionamide.

(iii) Fluoride Ion Source

As noted above, the disclosed and claimed cleaning compositions include (iii) by a fluoride ion source including one or more of neat ammonium fluoride and neat HF. Fluoride ion function principally to assist in removal of photoresist and post etch residues. Typical compounds that provide a fluoride ion source according to the disclosed and claimed subject matter are hydrofluoric acid, ammonium fluoride, quaternary ammonium fluorides, fluoroborates, fluoroboric acid, tetrabutylammonium tetrafluoroborate, aluminum hexafluoride, and a fluoride salt of an aliphatic primary, secondary or tertiary amine having the formula:

R¹NR²R³R⁴F

where R¹, R², R³ and R⁴ individually represent H or a (C₁-C₄) alkyl group. Typically, the total number of carbon atoms in the R¹, R², R³ and R⁴ groups is 12 carbon atoms or less. Examples of fluoride salts of an aliphatic primary, secondary or tertiary amine such as, for example, tetramethylammonium fluoride, tetraethylammonium fluoride, methyltriethylammonium fluoride and tetrabutylammonium fluoride.

In selecting the source of the fluoride ion, consideration should be given as to whether or not the source releases ions that would adversely affect the surface being cleaned. For example, in cleaning semiconductor elements, the presence of sodium or calcium ions in the cleaning solution can have an adverse effect on the surface of the element.

In one embodiment, the fluoride ion source is NH₄F. In one embodiment, the fluoride ion source is HF. In one embodiment, the fluoride ion source is a combination of NH₄F and HF. In some embodiments, when NH₄F is included as the fluoride ion source, it is provided as an aqueous solution including 40% ammonium fluoride. When HF is included as the fluoride ion source, commercial grade hydrofluoric acid can be used. Typically, the commercially available hydrofluoric acid is available as 5% to 70% aqueous solutions. In a preferred embodiment, electronic grade HF acid solutions are employed where such electronic grade solutions typically have a particle count below 100 particles/mL and where the size of the particles is less than or equal to 0.5 microns and metallic ions are present in the acid in the low parts per million to parts per billion level (volume).

In some specific embodiments, the fluoride ion source includes about 0.01 wt % to about 0.5 wt % of neat NH₄F. In some specific embodiments, the fluoride ion source includes about 0.01 wt % to about 0.1 wt % of neat NH₄F. In some specific embodiments, the fluoride ion source includes about 0.01 wt % to about 0.2 wt % of neat NH₄F. In some specific embodiments, the fluoride ion source includes about 0.01 wt % to about 0.3 wt % of neat NH₄F. In some specific embodiments, the fluoride ion source includes about 0.01 wt % to about 0.4 wt % of neat NH₄F. In some specific embodiments, the fluoride ion source includes about 0.05 wt % of neat NH₄F. In some specific embodiments, the fluoride ion source includes about 0.1 wt % of neat NH₄F. In some specific embodiments, the fluoride ion source includes about 0.2 wt % of neat NH₄F. In some specific embodiments, the fluoride ion source includes about 0.3 wt % of neat NH₄F. In some specific embodiments, the fluoride ion source includes about 0.4 wt % of neat NH₄F. In some specific embodiments, the fluoride ion source includes about 0.5 wt % of neat NH₄F.

In some specific embodiments, the fluoride ion source includes about 0.01 wt % to about 0.15 wt % of neat HF. In some specific embodiments, the fluoride ion source includes about 0.01 wt % to about 0.12 wt % of neat HF. In some specific embodiments, the fluoride ion source includes about 0.01 wt % to about 0.10 wt % of neat HF. In some specific embodiments, the fluoride ion source includes about 0.05 wt % to about 0.15 wt % of neat HF. In some specific embodiments, the fluoride ion source includes about 0.05 wt % to about 0.10 wt % of neat HF. In some specific embodiments, the fluoride ion source includes about 0.10 wt % to about 0.15 wt % of neat HF. In some specific embodiments, the fluoride ion source includes about 0.025 wt % of neat HF. In some specific embodiments, the fluoride ion source includes about 0.03 wt % of neat HF. In some specific embodiments, the fluoride ion source includes about 0.035 wt % of neat HF. In some specific embodiments, the fluoride ion source includes about 0.04 wt % of neat HF. In some specific embodiments, the fluoride ion source includes about 0.045 wt % of neat HF. In some specific embodiments, the fluoride ion source includes about 0.05 wt % of neat HF. In some specific embodiments, the fluoride ion source includes about 0.06 wt % of neat HF. In some specific embodiments, the fluoride ion source includes about 0.07 wt % of neat HF. In some specific embodiments, the fluoride ion source includes about 0.08 wt % of neat HF. In some specific embodiments, the fluoride ion source includes about 0.09 wt % of neat HF. In some specific embodiments, the fluoride ion source includes about 0.10 wt % of neat HF. In some specific embodiments, the fluoride ion source includes about 0.12 wt % of neat HF. In some specific embodiments, the fluoride ion source includes about 0.15 wt % of neat HF.

### (iv) Buffer Agent

As noted above, the disclosed and claimed cleaning compositions include (iv) one or more buffer agent. The buffer agent is used to adjust the pH of the cleaning compositions to a pH of between about 3 and about 9 which allows most sensitive metals to be cleaned with minimum corrosion.

Removal of highly inorganic etch residues and oxide skimming however requires a slightly acidic pH. As such, in some embodiments the pH of the cleaning compositions is adjusted to between about 3 and about 6 for optimal efficacy for cleaning etch residue. In other embodiments, the pH of the cleaning compositions is adjusted to between about 4 and about 6 for optimal efficacy for cleaning etch residue. In other embodiments, the pH of the cleaning compositions is adjusted to between about 4 and about 7 for optimal efficacy for cleaning etch residue.

A preferred buffer contains an ammonium salt of a carboxylic acid and/or a polybasic acid. An example of such an ammonium salt is an ammonium salt of acetic acid or phosphoric acid and citric acid. In one embodiment, for example, the buffer is an aqueous solution of ammonium acetate and acetic acid. Methods of preparing buffer solutions are well known in the art. The acidic buffer solutions, when added to the compositions of the disclosed and claimed subject matter provide a buffered composition with a pH adjusted to minimize corrosion of sensitive metals such as aluminum, copper, titanium, etc. the acidic buffer solution is added in an amount necessary to obtain the desired pH. The addition of the acidic buffer solutions prevents pH swings due to dilution with water or contamination by bases or acids.

In some embodiments, the disclosed and claimed compositions include buffer from about 1 wt % to about 10 wt. % of the composition. In other embodiments, the disclosed and claimed compositions include buffer from about 1 wt % to about 5 wt. %. In other embodiments, the disclosed and claimed compositions include about 1 wt. % of buffer. In other embodiments, the disclosed and claimed compositions include about 1.5 wt. % of buffer. In other embodiments, the disclosed and claimed compositions include about 2 wt. % of buffer. In other embodiments, the disclosed and claimed compositions include about 2.5 wt. % of buffer. In other embodiments, the disclosed and claimed compositions include about 3 wt. % of buffer. In other embodiments, the disclosed and claimed compositions include about 3.5 wt. % of buffer. In other embodiments, the disclosed and claimed compositions include about 4 wt. % of buffer. In other embodiments, the disclosed and claimed compositions include about 4.5 wt. % of buffer. In other embodiments, the disclosed and claimed compositions include about 5 wt. % of buffer. In other embodiments, the disclosed and claimed compositions include about 5.5 wt. % of buffer. In other embodiments, the disclosed and claimed compositions include about 6 wt. % of buffer. In other embodiments, the disclosed and claimed compositions include about 6.5 wt. % of buffer. In other embodiments, the disclosed and claimed compositions include about 7 wt. % of buffer. In other embodiments, the disclosed and claimed compositions include about 7.5 wt. % of buffer. In other embodiments, the disclosed and claimed compositions include about 8 wt. % of buffer. In other embodiments, the disclosed and claimed compositions include about 8.5 wt. % of buffer. In other embodiments, the disclosed and claimed compositions include about 9 wt. % of buffer. In other embodiments, the disclosed and claimed compositions include about 9.5 wt. % of buffer. In other embodiments, the disclosed and claimed compositions include about 10 wt. % of buffer.

In addition to the ranges above, the cleaning compositions may include an amount (total amount) of one or more buffer agent (neat) within a range having the start and end points from the following list of weight percents: 1, 1.5, 2, 2.5, 3, 4, 5, 6, 7, 8, 9, 10.

In one embodiment, the (iv) a buffer agent is an aqueous solution of ammonium acetate and acetic acid. In one aspect of this embodiment, the (iv) a buffer agent includes about 4.0% to about 5.0% by weight of the aqueous solution of ammonium acetate and acetic acid. In one aspect of this embodiment, the (iv) a buffer agent includes about 4.25% to about 4.75% by weight of the aqueous solution of ammonium acetate and acetic acid. In one aspect of this embodiment, the (iv) a buffer agent includes about 4.5% by weight of the aqueous solution of ammonium acetate and acetic acid. In one aspect of this embodiment, the (iv) a buffer agent includes about 4.6% by weight of the aqueous solution of ammonium acetate and acetic acid. In one aspect of this embodiment, the (iv) a buffer agent includes about 4.7% by weight of the aqueous solution of ammonium acetate and acetic acid. In one aspect of this embodiment, the (iv) a buffer agent includes about 1.5% to about 3.0% by weight of ammonium acetate and about 1.5% to about 3.0% by weight of acetic acid. In one aspect of this embodiment, the (iv) a buffer agent includes about 2.0% to about 3.0% by weight of ammonium acetate and about 1.5% to about 2.5% by weight of acetic acid. In one aspect of this embodiment, the (iv) a buffer agent includes about 2.5% by weight of ammonium acetate and about 2.0% by weight of acetic acid. In one aspect of this embodiment, the (iv) a buffer agent includes about 2.6% by weight of ammonium acetate and about 2.0% by weight of acetic acid.

### (v) Water

The disclosed and claimed cleaning compositions are aqueous-based and, thus, include water. The water functions in various ways such as, for example, to dissolve one or more solid components of the composition, as a carrier of the components, as an aid to facilitate the removal of inorganic salts and complexes, as a viscosity modifier of the composition, and as a diluent. Preferably, the water employed in the cleaning compositions is deionized water (DIW) water.

In one embodiment, the cleaning compositions include from about 10% to about 40% or from about 20% to about 40% by wt. of water. In other embodiments, the cleaning compositions include from about 25% to about 35% by wt. of water.

The amount of (v) water in the disclosed and claimed compositions may be in any range having any of the lower and upper endpoints selected from the group of 10, 11, 13, 25, 26, 29, 30, 31, 32, 34, 36, 39, 40% by wt. of the cleaning composition. For example, the amount of water may range from about 10 wt % to about 40 wt % or from about 15 wt % to about 35 wt % or from about 20% to about 35 wt % or any other combination of lower and upper endpoints. In some embodiments, for example, the amount of water may range from about 10 wt % to about 30 wt %, about 20 wt % to about 30 wt %, about 25 wt % to about 35 wt %, about 20 wt % to about 40 wt %, about 20 wt % to about 45 wt %, about 25 wt % to about 32 wt %, about 30 wt % to about 35 wt %, about 28 wt % to about 32 wt %, about 29 wt % to about 35 wt %. Those skilled in the art will recognize that the amounts of water may be varied in and around these ranges and still fall within the scope of the disclosed and claimed subject matter.

### (vi) Optional Corrosion Inhibitor

The compositions of the disclosed and claimed subject matter further optionally include one or more corrosion inhibitor. Corrosion inhibitors serve to react with any metal exposed on the substrate surface being etched, particularly copper, or a nonmetal, to passivate the surface and prevent excessive etching during cleaning. Examples of corrosion-inhibitors include carboxyl group-containing organic compounds and anhydrides thereof, and triazole compounds, and imidazole compounds.

Exemplary carboxyl group-containing organic compounds and anhydrides thereof include formic acid, propionic acid, butyric acid, isobutyric acid, oxalic acid, malonic acid, succinic acid, glutaric acid, maleic acid, fumaric acid, benzoic acid, phthalic acid, 1,2,3-benzenetricarboxylic acid, glycolic acid, lactic acid, maleic acid, acetic anhydride and salicylic acid.

Exemplary triazole compounds include benzotriazole, o-tolyltriazole, m-tolyltriazole, p-tolyltriazole, carboxybenzotriazole, 1-hydroxybenzotriazole, nitrobenzotriazole and dihydroxypropylbenzotriazole.

Exemplary imidizole compounds include benzimidazole and 2-mercaptobenzimidazole.

In an exemplary embodiment, the one or more corrosion inhibitor in the composition of the disclosed and claimed subject matter include one or more of benzotriazole, carboxybenzotriazole, amino-benzotriazole, D-fructose, t-butyl catechol, L-ascorbic acid, vanillin, salicylic acid, diethyl hydroxylamine, and poly (ethyleneimine), 2-mercaptobenzimidazole.

In other embodiments, the one or more than one corrosion inhibitor is a triazole and is at least one of benzotriazole, o-tolyltriazole, m-tolyltriazole, and p-tolyltriazole, more preferably the corrosion inhibitor includes benzotriazole.

If present, the disclosed and claimed compositions will include the one or more corrosion inhibitor (neat) from about 0.1 to about 15 wt. % of the composition; preferably it includes from about 0.1 to about 10 wt. %, preferably, from about 0.5 to about 5 wt. %, and most preferably, from about 0.1 to about 1 wt. %, or about 0.1 to about 0.5 wt. % of the composition. In addition to the ranges above, the disclosed and claimed compositions may include an amount (total amount) of the one or more corrosion inhibitor (neat) within a range having the start and end points from the following list of weight percents: 0.1, 0.2, 0.25, 0.4, 0.5, 1, 1.5, 2, 2.5, 3, 4, 5, 6, 7, 8, 9, 10 and 15.

In another embodiment, the disclosed and claimed compositions are substantially free of corrosion inhibitors.

In another embodiment, the disclosed and claimed compositions are free of corrosion inhibitors.

### Other Optionally Excluded Ingredients

In other embodiments, the compositions may include, be substantially free of or be free of any or all of oxidizers, surfactants, chemical modifiers, dyes and/or biocides.

In some embodiments, the compositions of the disclosed and claimed subject matter may be free of or substantially free of at least one, or more than one in any combination, or all of the following, or free of any additional of the following if already present in the composition: sulfur-containing compounds, bromine-containing compounds, chlorine-containing compounds, iodine-containing compounds, halogen-containing compounds, phosphorus-containing compounds, metal-containing compounds, sodium-containing compounds, calcium-containing compounds, alkyl thiols, organic silanes, lithium-containing compound, silicon-containing compounds, oxidizing agents, peroxides, buffer species, polymers, inorganic acids, amides, metal hydroxides and abrasives.

### Methods of Use

The disclosed and claimed subject matter further includes a method of removing, in whole or on part, one or more photoresists or similar materials from a substrate using one or of the disclosed and claims photoresist stripper solutions. As noted above, the disclosed and claimed photoresist stripper solutions can be used to remove polymeric resist materials present in a single layer or certain types of bilayer resists. Utilizing the methods taught below, a single layer of polymeric resist can be effectively removed from a standard wafer having a single polymer layer. The same methods can also be used to remove a single polymer layer from a wafer having a bilayer composed of a first inorganic layer and a second or outer polymer layer. Finally, two polymer layers can be effectively removed from a wafer having a bilayer composed of two polymeric layers.

In one aspect of this embodiment, the process or method for removing a photoresist or similar material from a substrate includes the steps of:
(i) contacting the substrate with one or more of the photoresist stripper solutions for a time sufficient to remove a desired amount of the photoresist or similar material,
(ii) removing the substrate from the stripping solution,
(iii) rinsing the stripping solution from the substrate with DI water or a solvent, and
(iv) optionally drying the substrate.

In one embodiment, step (i) includes immersing the substrate one or more of the photoresist stripper solutions and optionally agitating the substrate to facilitate photoresist removal. Such agitation can be affected by mechanical stirring, circulating or by bubbling an inert gas through the composition.

In one embodiment, step (ii) includes rinsing the substrate rinsed with water or an alcohol. In one aspect of this embodiment, deionized (“DI”) water is a preferred form of water. In another aspect of this embodiment, isopropanol (IPA) is a preferred solvent. In another aspect of this embodiment, components subject to oxidation are or can be rinsed under an inert atmosphere.

Utilizing the above methods (as well as variants thereof), the disclosed and claimed photoresist stripper solutions can be used for removal of thick and thin positive or negative tone photoresists. Thick photoresists may be a resist of from about 5 μm to about 100 μm or more, or about 15 μm to 100 μm, or from about 20 μm to about 100 μm in advanced packaging applications for semiconductor devices. In other cases, the chemical solutions may be used to remove photoresist from about 1 μm to about 100 μm or more, or about 2 μm to 100 μm, or from about 3 μm to about 100 μm.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents. The abbreviations used in the Examples are as follows:

| Abbreviation | Full Name |
|---|---|
| BZT | Benzotriazole |
| NMP | N-Methyl-2-Pyrrolidone |
| DMAC | Dimethylacetamide |
| PG | Propylene Glycol |
| DPM | Dipropylene Glycol Monomethyl Ether |
| BDG | Diethylene Glycol Butyl Ether |
| DEF | Diethyl Formamide |

The photoresist removal ability was measured by optical microscope. Silicon oxide and TEOS film etch rates were estimated from changes in the thickness before and after etching and was measured by spectroscopic ellipsometry SCI FilmTek SE2000. Typical starting layer thickness was 1000 Å for silicon oxide. ITO, aluminum, titanium etch rates were estimated from changes in the thickness before and after etching and was measured by CDE Resmap. Typical starting layer thickness was 1000 Å for ITO, Al and Ti substrates. All the beaker tests and etch rate tests were carried out at from ambient temperature to 60° C. Data were reported at 40° C. and 35° C. Wafer coupons of various substrates were immersed in formulations at desired process temperatures and process times. After DIW rinsing, wafer coupons were blown-dried by nitrogen gas. Film thickness was measured by CDS Resmap (metallic substrate) or ellipsometer (dielectric substrate). Film thickness difference was calculated before/after formulation immersion and etch rate was deducted using process time. The cleaning tests were performed by immersing the pattern wafer substrates in the formulations for certain time. After wafer rinse, the substrates were dried by N₂ blowing. The cleaning performance was then evaluated by SEM. In general, clean performance was acceptable when the post-etched residue along the sidewall was effectively removed. Besides, no discernible damage on the substrate should be observed. This could be also confirmed with etch rate data of the substrates. If the formulation is compatible with the substrate, low etch rate of substrates should be observed.

TABLE 1
Fluoride Effect on Amount of Photoresist Etching

| Component | % | CAS | 1 | 2 |
|---|---|---|---|---|
| H₂O | 100 | | 29.25 | 30.5 |
| Ammonium Acetate | 100 | 631-61-8 | 2.6 | 2.6 |
| Acetic Acid | 100 | 64-19-7 | 2 | 2 |
| NH₄F | 40 | 12125-01-8 | 1.25 | — |
| BZT | 100 | 95-14-7 | 1 | 1 |
| NMP | 100 | 872-50-4 | 63.9 | 63.9 |

| | | |
|---|---|---|
| Total | 100 | 100 |
| Photoresist Etching Amount | 12 μm | 0 μm |

Table 1 shows that the formulation 1 containing fluoride ions resulted in 12 μm removal of photoresist layer while formulation 2 which excludes fluoride ions did not show any photoresist etch, suggesting the presence of fluoride ion was a key component for photoresist removal.

TABLE 2
Effect of Acidic Fluoride Solution

| Component | % | CAS | 1 | 2 | 3 | 4 | 5 |
|---|---|---|---|---|---|---|---|
| H₂O | 100 | | 29.25 | 29.25 | 29.25 | 29.25 | 29.25 |
| Ammonium Acetate | 100 | 631-61-8 | 2.6 | 2.6 | 2.6 | 2.6 | 2.6 |
| Acetic Acid | 100 | 64-19-7 | 2 | 2 | 2 | 2 | 2 |
| NH₄F | 40 | 12125-01-8 | 1.25 | 1.25 | 1.25 | 1.25 | 1.25 |
| BZT | 100 | 95-14-7 | 1 | 1 | 1 | 1 | 1 |
| NMP | 100 | 872-50-4 | 63.9 | — | — | — | — |
| DMAC | 100 | 169117-72-0 | — | 63.9 | — | — | — |
| PG | 100 | 57-55-6 | — | — | 63.9 | — | — |
| DPM | 100 | 34590-94-8 | — | — | — | 63.9 | — |
| BDG | 100 | 112-34-5 | — | — | — | — | 63.9 |

| | | | | | |
|---|---|---|---|---|---|
| Total | 100 | 100 | 100 | 100 | 100 |
| Photoresist Etching Amount | 12 μm | 2 μm | 5 μm | 12 μm | 18 μm |
| SiO₂ Etch Rate | 23.4 | 7.8 | 12.5 | 38.1 | 56.2 |
| ITO Etch Rate | 0.44 | 0.32 | 0.49 | 1.2 | 2.1 |
| Cleaning | good | N/A | poor | N/A | good |

Table 2 shows the effect on the amount of photoresist removal and cleaning performance of when using different solvents in combination with fluoride ions. Among those solvents, BDG based formulation 5 showed similar cleaning performance to NMP based formulation 1, however, higher photoresist removal amount and SiO₂ etch rate were observed. PG based formulation 3 showed much less photoresist removal amount and lower SiO₂ etch rates; however, the cleaning performance was poor. Other solvents did not have significant effect on ITO etch rates. All ITO etch rates were low, suggesting all fluoride formulations had good compatibility to ITO substrates.

TABLE 3
Photoresist Removal Using Co-Solvent System

| Component | % | CAS | 3 | 6 | 7 | 5 |
|---|---|---|---|---|---|---|
| H₂O | 100 | | 29.25 | 29.25 | 29.25 | 29.25 |
| Ammonium Acetate | 100 | 631-61-8 | 2.6 | 2.6 | 2.6 | 2.6 |
| Acetic Acid | 100 | 64-19-7 | 2 | 2 | 2 | 2 |
| NH₄F | 40 | 12125-01-8 | 1.25 | 1.25 | 1.25 | 1.25 |
| BZT | 100 | 95-14-7 | 1 | 1 | 1 | 1 |
| PG | 100 | 57-55-6 | 63.9 | 40 | 23.9 | — |
| BDG | 100 | 112-34-5 | — | 23.9 | 40 | 63.9 |

| | | | | |
|---|---|---|---|---|
| Total | 36.1 | 100 | 100 | 100 |
| Photoresist Etching Amount | 5 μm | 9 μm | 12 μm | 18 μm |
| SiO₂ Etch Rate | 7.8 | 12.5 | 23.6 | 38.1 |
| Cleaning | Not good | fair | fair | good |

Table 3 shows that by adding over 20% PG into BDG based formulations, both the photoresist etch amount and SiO₂ etch rates were lowered however cleaning performance still needed to improve.

TABLE 4
Effects of Mixed Solvent System

| Component | % | CAS | 6 | 7 | 8 | 9 | 10 | 11 |
|---|---|---|---|---|---|---|---|---|
| H₂O | 100 | | 29.25 | 29.25 | 29.25 | 29.25 | 29.8 | 29.8 |
| Ammonium Acetate | 100 | 631-61-8 | 2.6 | 2.6 | 2.6 | 2.6 | 2.6 | 2.6 |
| Acetic Acid | 100 | 64-19-7 | 2 | 2 | 2 | 2 | 2 | 2 |
| NH₄F | 40 | 12125-01-8 | 1.25 | 1.25 | 1.25 | 1.25 | 0.7 | 0.7 |
| BZT | 100 | 95-14-7 | 1 | 1 | 1 | 1 | 1 | 1 |
| PG | 100 | 57-55-6 | 40 | 23.9 | 5 | 10 | 5 | 10 |
| BDG | 100 | 112-34-5 | 23.9 | 40 | 58.9 | 53.9 | 58.9 | 53.9 |

| | | | | | | |
|---|---|---|---|---|---|---|
| Total | 100 | 100 | 100 | 100 | 100 | 100 |
| SiO₂ Etch Rate | 12.5 | 23.6 | 45.8 | 41.7 | 22.9 | 21.7 |
| Cleaning | fair | fair | good | good | good | good |

Table 4 shows that when comparing formulations 6 and 7, lowering PG concentration below 10% resulted in an obvious increase in SiO₂ etch rate although the cleaning performance was improved. The SiO₂ etch rates were decreased by lowering fluoride concentration in PG and BDG mix solvent-based formulations without affecting cleaning performance.

TABLE 5

| Raw Material | 10 | 11 | 12 | 13 |
|---|---|---|---|---|
| DEF | — | — | — | 58.6 |
| BDG | 58.9 | 58.9 | 57.2 | |
| DIW | 29.8 | 17 | 17 | 29.3 |
| Ammonium acetate | 2.6 | 2.6 | 2.6 | 2.6 |
| Acetic Acid | 2 | 2 | 2 | 2 |
| Ammonium Fluoride (40%) | 0.7 | 1.1 | 2.8 | 3.5 |
| PG | 5 | 18.4 | 18.4 | 4 |
| BZT | 1 | 0 | 0 | — |
| Total | 100 | 100 | 100 | 100 |
| TEOS SiO₂ loss @ | 202.6 | 217.2 | 220.2 | 219.8 |
| 35° C. 10 min | | | | |
| Al loss @ 35° C. 10 min | 154 | 106 | 95.6 | 105 |
| Ti loss @ 35° C. 10 min | 18.3 | 21.3 | 22.1 | 24.1 |
| Cleaning on Al residues | Minor | Minor | Minor | good |
| | Clean | clean | clean | |
| Cleaning on Via residues | good | good | good | good |

Table 5 illustrates the cleaning performance on post etch residues which are aluminum containing residues and silicon containing residues in the formulations containing different solvents. Formulations using BDG and PG showed minor residues on the substrates after cleaning. On the other hand, formulations 13 which contains only one solvent DEF showed good cleaning performance. These results showed that the polarity of DEF played a key role on the removal of Al-containing residue. Only DEF solvent can effectively remove post-etched residue, formulations using BDG and PG still showed some post etched residue after cleaning.

Although the disclosed and claimed subject matter has been described and illustrated with a certain degree of particularity, it is understood that the disclosure has been made only by way of example, and that numerous changes in the conditions and order of steps can be resorted to by those skilled in the art without departing from the spirit and scope of the disclosed and claimed subject matter.

1. A composition comprising
(i) about 1% to about 10% by weight of one or more polyhydric alcohol;
(ii) about 50% to about 80% by weight of (iia) one or more organic water-soluble glycol ether solvent or (iib) one or more amide selected from diethyl formamide (DEF), N-methylformamide, N-ethylformamide, N,N-dimethylacetamide or N,N-dimethylpropionamide;
(iii) about 0.1% to about 0.5% by weight of a fluoride ion source including one or more of neat ammonium fluoride and neat HF;
(iv) about 1% to about 10% by weight of one or more buffer agent;
(v) about 10% to about 40% by weight of water; and
(vi) optionally one or more corrosion inhibitor.

2. (canceled)

3. (canceled)

4. The composition of claim 1, wherein the composition has a pH of more than about 3 and less than about 6.

5-7. (canceled)

8. The composition of claim 1, wherein the compositions disclosed herein are free of at least one of 4-methylmorpholine N-oxide, trimethylamine N-oxide, peracetic acid, urea, hydrogen peroxide, amidoxime compounds hydroxylamine, hydroxylamine derivatives and metal-containing compounds.

9. (canceled)

10. The composition of claim 1, wherein the (i) one or more polyhydric alcohol in the disclosed and claimed compositions is from about 1% to about 10% by weight of the composition and is one or more of glycerol, ethylene glycol, propylene glycol, diethylene glycol, dipropylene glycol, hexylene glycol, 1,2-butandiol, 1,4-butandiol and 2,3-butandiol.

11-15. (canceled)

16. The composition of claim 1, wherein the (i) one or more polyhydric alcohol consists of about 5% to about 10% by weight of propylene glycol.

17. (canceled)

18. (canceled)

19. The cleaning composition of claim 1, wherein the (iia) one or more organic water-soluble glycol ether solvent comprises about 50% to about 60% by weight of diethylene glycol butyl ether (BDG).

20-24. (canceled)

25. The composition of claim 1, wherein the composition comprises (iib) one or more amide selected from diethyl formamide (DEF), N-methylformamide, N-ethylformamide, N,N-dimethylacetamide and N,N-dimethylpropionamide.

26. (canceled)

27. The composition of claim 1, wherein the composition comprises about 50% to about 60% by weight of (iib) diethyl formamide.

28-36. (canceled)

37. The composition of claim 1, wherein the composition comprises about 50% to about 60% by weight of (iib)N-methylformamide.

38-42. (canceled)

43. The composition of claim 1, wherein the composition comprises about 50% to about 60% by weight of (iib) N,N-dimethylacetamide.

44. (canceled)

45. (canceled)

46. The composition of claim 1, wherein the composition comprises about 50% to about 60% by weight of (iib) N,N-dimethylpropionamide.

47-49. (canceled)

50. The composition of claim 1, wherein the (iii) fluoride ion source comprises one or both of neat ammonium fluoride and neat HF.

51. The composition of claim 1, wherein the (iii) fluoride ion source is neat ammonium fluoride and is from about 0.01 wt % to about 0.5 wt % of the composition.

52-55. (canceled)

56. The composition of claim 1, wherein the (iii) fluoride ion source is neat HF and is from about 0.01 wt % to about 0.15 wt % of the composition.

57-62. (canceled)

63. The composition of claim 1, wherein the (iv) buffer agent is from about 1 wt % to about 10 wt % of the composition and comprises an aqueous solution of ammonium acetate and acetic acid.

64-70. (canceled)

71. The composition of claim 1, wherein the (v) water is from about 10 wt % to about 40 wt % of the composition.

72-77. (canceled)

78. The composition of claim 1, wherein the (vi) one or more corrosion inhibitor is comprises from about 0.1 wt % to about 15 wt % of the composition and comprises one or more of benzotriazole, o-tolyltriazole, m-tolyltriazole, and p-tolyltriazole.

79-84. (canceled)

85. The composition of claim 1, wherein the (i) polyhydric alcohol consists of about 5% to about 10% by weight of propylene glycol (PG) and the (ii) organic water-soluble glycol ether solvent consists of about 50% to about 60% by weight of diethylene glycol butyl ether (BDG).

86-89. (canceled)

90. The composition of claim 1, wherein
the (i) one or more polyhydric alcohol consists of about 5% by weight of propylene glycol (PG);
the (ii) one or more organic water-soluble glycol ether solvent consists of about 58.9% by weight of diethylene glycol butyl ether (BDG);
the (iii) fluoride ion source consists of about 0.28% by weight of neat ammonium fluoride;
the (iv) one or more buffer agent consists of about 2.6% by weight of ammonium acetate and about 2.0% by weight of acetic acid; and
a balance of the formulation is the (v) water.

91. The cleaning composition of claim 90, wherein the (vi) optional one or more corrosion inhibitor is present and consists of about 1% by weight of benzotriazole.

92. The composition of claim 1, wherein
the (i) one or more polyhydric alcohol consists of about 10% by weight of propylene glycol (PG);
the (ii) one or more organic water-soluble glycol ether solvent consists of about 53.9% by weight of diethylene glycol butyl ether (BDG);
the (iii) fluoride ion source consists of about 0.28% by weight of neat ammonium fluoride;
the (iv) one or more buffer agent consists of about 2.6% by weight of ammonium acetate and about 2.0% by weight of acetic acid; and
a balance of the formulation is the (v) water.

93. The cleaning composition of claim 92, wherein the (vi) optional one or more corrosion inhibitor is present and consists of about 1% by weight of benzotriazole.

94. The composition of claim 1, wherein
the (i) one or more polyhydric alcohol consists of about 4% by weight of propylene glycol (PG);
the (iib) diethyl formamide consists of about 58.6% by weight of diethyl formamide;
the (iii) fluoride ion source consists of about 3.5% by weight of neat ammonium fluoride;
the (iv) one or more buffer agent consists of about 2.6% by weight of ammonium acetate and about 2.0% by weight of acetic acid; and
a balance of the formulation is the (v) water.

95. A method for removing a photoresist or similar material from a substrate comprising the steps of:
(i) contacting the substrate with one or more of the photoresist stripper solutions of claim 1 for a time sufficient to remove a desired amount of the photoresist or similar material,
(ii) removing the substrate from the stripping solution,
(iii) rinsing the stripping solution from the substrate with DI water or a solvent, and
(iv) optionally drying the substrate.
